(19) United States
(12) Patent Application Publication
(10) Pub. No.: US 2006/0119485 A1
(43) Pub. Date: Jun. 8, 2006

(54) Computer and control method thereof

(75) Inventors: Byeong-chang Lee, Yongin-si (KR); Seung-loon Park, Suwon-si (KR)

Correspondence Address: STAAS & HALSEY LLP, SUITE 700, 1201 NEW YORK AVENUE, N.W., WASHINGTON, DC, 20005, US

(73) Assignee: SAMSUNG ELECTRONICS CO., LTD., Suwon-si (KR)

(21) Appl. No.: 11/264,018

(22) Filed: Nov. 2, 2005

(30) Foreign Application Priority Data
Nov. 25, 2004 (KR) 10-2004-0097688

(51) Int. Cl. G08B 25/08; H03G 5/00

(52) U.S. Cl. 340/692; 381/99

(57) ABSTRACT

A computer having a speaker outputting a sound, the computer including: a sound signal output unit outputting a speaker sound signal to the speaker; a speaker output control unit controlling whether the sound signal output unit to output the speaker sound signal; and an alarm control unit controlling the speaker output control unit so that the sound signal output unit outputs the speaker sound signal when a predetermined alarm condition is detected, and the sound signal output unit so that the speaker generates a preset alarm sound to correspond to the alarm condition.

### CROSS-REFERENCE TO RELATED APPLICATION

This application claims the benefit of Korean Patent Application No. 10-2004-0097688, filed on Nov. 25, 2004, in the Korean Intellectual Property Office, the disclosure of which is incorporated herein by reference.

### BACKGROUND OF THE INVENTION

1. Field of the Invention

The present invention relates to a computer and a control method thereof, and more particularly, to a computer and a control method thereof canceling a mute mode of a speaker and generating an alarm sound through the speaker when a predetermined alarm condition is detected.

2. Description of Related Art

Generally, computers are classified into desktop computers seated on a certain installation surface like a desk and portable computers which are small and lightweight enough for a user to carry from place to place.

Portable computers, which are supplied with power from a battery, include laptop computers, notebook computers, PDAs (personal digital assistants), and tablet computers, for example.

These conventional computers have an alarm function which generates an alarm sound through an internal speaker when the computer is under a certain condition.

For example, portable computers face many chances to be stolen because the portable computers are easy to be carried and moved. Thus, portable computers have come to have the alarm function generating the alarm sound through the within speaker in the case that someone tries to steal the portable computer. In Korean Patent First Publication No. 2000-74911 is disclosed the portable computer automatically generating the alarm sound when a theft is tried on the computer.

However, such a computer cannot generate the alarm sound when the within speaker is under a disabled condition, even though the theft is detected.

For example, when an external speaker such as earphones or headphones is connected with the computer, the within speaker is not activated. In that case, the alarm sound is outputted through the external speaker, and the computer cannot display its alarm function properly.

### BRIEF SUMMARY

Accordingly, it is an aspect of the present invention to provide a computer and a control method thereof canceling a condition of a within speaker being disabled and generating an alarm sound through the speaker when a predetermined alarm condition is detected.

According to an aspect of the present invention, there is provided a computer having a speaker outputting a sound, the computer comprising: a sound signal output unit outputting a speaker sound signal to the speaker; a speaker output control unit controlling whether the sound signal output unit outputs the speaker sound signal; and an alarm control unit controlling the speaker output control unit so that the sound signal output unit outputs the speaker sound signal when a predetermined alarm condition is detected, and controlling the sound signal output unit so that the speaker generates a preset alarm corresponding to the alarm condition.

The sound signal output unit may include an audio codec converting an inputted signal into an analog sound signal and a speaker amp outputting the speaker sound signal by amplifying the analog sound signal outputted from the audio codec; the speaker output control unit controls whether the speaker amp to be activated, and whether the speaker sound signal to be outputted.

The sound signal output unit may further include an external output amp outputting an external output sound signal by amplifying the analog sound signal outputted from the audio codec into the external output sound signal, and an external connection terminal with which an external speaker is connected in order to output the external output sound signal to the external speaker; the speaker output control unit comprises a connection detecting unit detecting whether the external speaker is connected with the external connection terminal, and a logic operation unit controlling the speaker amp to output the speaker sound signal regardless of whether the external speaker is connected with the external connection terminal when the alarm condition is detected.

The logic operation unit may control the speaker amp not to output the speaker sound signal when the connection detecting unit detects the external speaker is connected under the condition that the alarm condition is not detected.

The alarm control unit may include: an alarm detecting unit detecting the alarm condition; and an alarm generating unit controlling the speaker output control unit and/or the sound signal output unit to respond to the alarm condition when the alarm detecting unit detects the alarm condition.

The alarm generating unit may include: an audio controller supplying sound data to the audio codec; a microcomputer generating a predetermined interrupt signal when the alarm detecting unit detects the alarm condition; and a control routine unit controlling the audio controller so that the sound signal output unit outputs the alarm sound through the speaker according to the interrupt signal generated from the microcomputer.

Either the microcomputer or the audio controller may output a signal corresponding to a detecting result of the alarm detecting unit to the logic operation unit.

The control routine unit may perform a system initializing process when the computer is turned on, requests input of a preset password while performing the system initializing process, and controls the audio controller so that the sound signal output unit outputs the alarm sound through the speaker when a password input in response to a request to input the preset password is inconsistent with the preset password at least a predetermined number of times.

According to another aspect of the present invention, there is provided a control method of a computer having a speaker outputting a sound and a sound signal output unit outputting a speaker sound signal through the speaker, the control method comprising: disabling the sound signal output unit from being activated; detecting whether a predetermined alarm condition occurs; and enabling the sound signal output unit so that a preset alarm sound corresponding to the alarm condition is outputted through the speaker when the alarm condition is detected.

The sound signal output unit may include a speaker amp amplifying an analog sound signal into a speaker sound signal and outputting the speaker sound signal, an external output amp amplifying the analog sound signal into an external output sound signal and outputting the external output sound signal, and an external connection terminal with which an external speaker is connected so that the external output sound signal is outputted to the external speaker; the disabling the sound signal output unit comprises disabling the speaker amp from being activated when the external connection terminal is connected with the external speaker.

The enabling the sound signal output unit may include enabling the speaker amp to be activated regardless of whether the external speaker is connected with the external connection terminal when the alarm condition is detected.

According to another embodiment of the present invention, there is provided a computer including: sound signal output means for outputting a speaker sound signal to the speaker; speaker output control means for controlling whether the sound signal output means outputs the speaker sound signal; and alarm control means for controlling the speaker output control means so that the sound signal output means outputs the speaker sound signal when a predetermined alarm condition is detected, and controlling the sound signal output means so that the speaker generates a preset alarm sound corresponding to the alarm condition.

Additional and/or other aspects and advantages of the present invention will be set forth in part in the description which follows and, in part, will be obvious from the description, or may be learned by practice of the invention.

### BRIEF DESCRIPTION OF THE DRAWINGS

The above and/or other aspects and advantages of the present invention will become apparent and more readily appreciated from the following description of the exemplary embodiments, taken in conjunction with the accompanying drawings of which:

FIG. 1 is a perspective view of a computer according to an embodiment of the present invention;

FIG. 2 is a control block diagram of a computer according to an embodiment of the present invention;

FIGS. 3 and 4 are detailed control block diagrams of the computer of FIG. 2; and

FIG. 5 is a flowchart describing a control method for the computer according to an embodiment of the present invention.

### DETAILED DESCRIPTION OF EMBODIMENTS

Reference will now be made in detail to exemplary embodiments of the present invention, examples of which are illustrated in the accompanying drawings, wherein like reference numerals refer to like elements throughout. The embodiments are described below in order to explain the present invention by referring to the figures.

Herein, a portable computer like a notebook computer is introduced as an example of a computer 100 according to an embodiment of the present invention. However, it is to be understood that the computer 100 includes other kinds of computers to which the present invention can be applied.

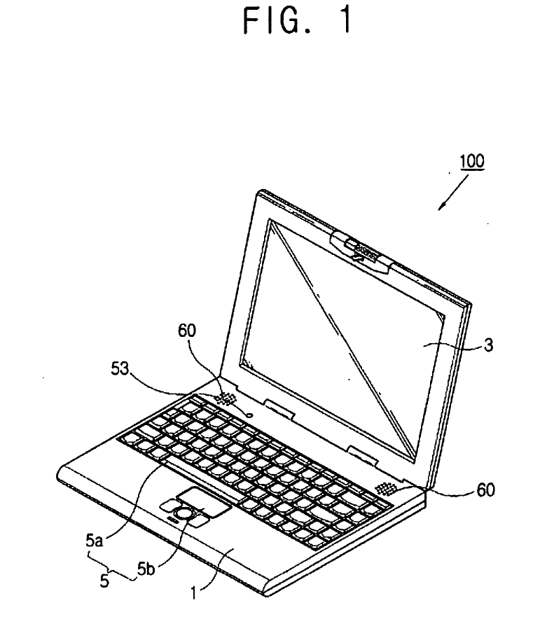

FIG. 1 is a perspective view of the computer 100 according to an embodiment of the present invention. As shown therein, the computer 100 comprises a main body 1 and a display unit 3 rotatably combined with the main body 1.

The display unit 3 displays thereon picture data supplied from the main body 1 as an image. Here, the display unit 3 may employ a display panel of an LCD (liquid crystal display).

In the main body 1 are provided an input part 5 such as a keyboard 5a for inputting key signals, a touch pad 5b, and etc. Inside the main body 1 are provided electronic components for performing functions of the computer 100, and the electronic components will be described later.

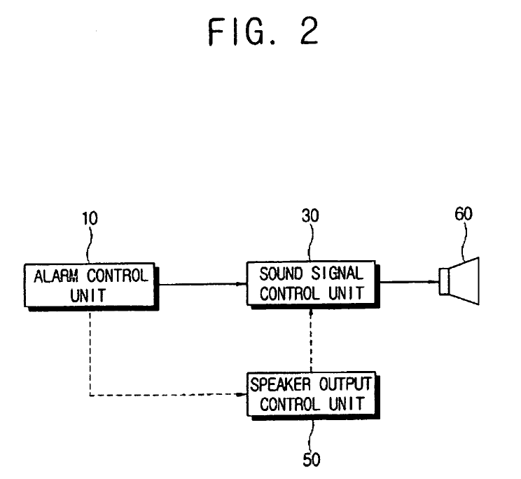

FIG. 2 is a block diagram showing a configuration of the computer 100 for generating an alarm sound according to a predetermined alarm condition. As shown therein, the computer 100 comprises a speaker 60, a sound signal output unit 30, a speaker output control unit 50, and an alarm control unit 10.

A speaker sound signal outputted from the sound signal output unit 30 is inputted to the speaker 60, and then outputted to the outside of the computer 100 as a sound through the speaker 60. Here, the speaker 60 may be disposed in a portion of the main body 1 or the display unit 3. In FIG. 1, the speaker 60 is disposed at opposite upper sides of the main body 1.

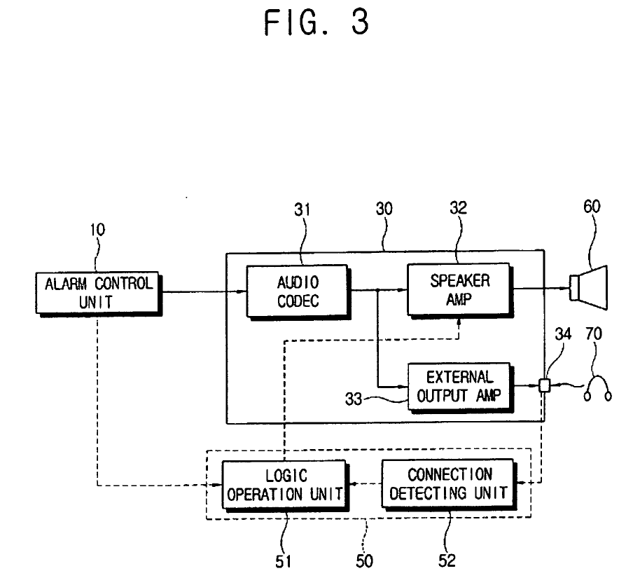

The sound signal output unit 30 outputs the speaker sound signal to the speaker 60. As shown in FIG. 3, the sound signal output unit 30 may comprise an audio coder/decoder (codec) 31 and a speaker amplifying unit (amp) 32. Also as shown in FIG. 3, the sound signal output unit 30 may further comprise an external output amp 33 and an external connection terminal 34.

The audio codec 31 converts an inputted signal into analog a sound signal, and outputs the analog sound signal The speaker amp 32 amplifies the analog sound signal outputted from the audio codec 31 into the speaker sound signal, and then outputs the speaker sound signal. Here, the speaker sound signal outputted from the speaker amp 32 is outputted as the sound through the speaker 60.

The external output amp 33 amplifies the analog sound signal outputted from the audio codec 31 into an external output sound signal, and then outputs the external output sound signal. Here, the external output sound signal outputted from the external output amp 33 is outputted to an external speaker 70 connected with the external connection terminal 34 such as earphones, headphones, or etc.

The speaker output control unit 50 controls the sound signal output unit 30 to output or not to output the speaker sound signal. Further, the speaker output control unit 50 controls the speaker sound signal to output or not to output by controlling the speaker amp 32 to or not to be activated. Therefore, the speaker output control unit 50 controls the speaker 60 to output or not to output the sound.

The alarm control unit 10 controls the speaker output control unit 50 so that the sound signal output unit 30 outputs the speaker sound signal if a predetermined alarm condition is detected. Also, the alarm control unit 10 controls the sound signal output unit 30 so that a preset alarm sound is outputted through the speaker 60 to correspond to the alarm condition.

Here, the alarm control unit 10 may control the audio codec 31 to output the sound provided therein, for example, a PC beep signal, to the speaker 60 through the speaker amp 32 if the alarm condition is detected. Namely, the alarm control unit 10 controls the audio codec 31 to output the PC Beep signal provided therein to the speaker amp 32 by converting a logic value of a certain pin in the audio codec 31, so that the alarm sound is outputted through the speaker 60 when the alarm condition is detected.

As shown in FIG. 3, the speaker output control unit 50 may comprise a connection detecting unit 52 and a logic operation unit 51.

The connection detecting unit 52 detects whether the external speaker such is connected with the external connection terminal 34. Here, the connection detecting unit 52 may comprise a circuit having the logic values varying according to whether or not the external connection terminal 34 is connected with the external speaker 70. Accordingly, the connection detecting unit 52 outputs a detection signal, having the logic value corresponding to whether or not the external speaker 70 is connected, to the logic operation unit 51.

The logic operation unit 51 receives an alarm signal, having the logic value corresponding to whether or not the alarm condition is detected, from the alarm control unit 10. Also, the logic operation unit 51 receives the detection signal, having the logic value corresponding to whether or not the external speaker 70 is connected, from the connection detecting unit 52.

The logic operation unit 51 controls the speaker amp 32 to or not to be activated by logically operating the alarm signal received from the alarm control unit 10 and the detection signal received from the connection detecting unit 52. Here, the logic operation unit 51 controls the speaker amp 32 to be activated and to output the speaker sound signal regardless of the logic value of the detection signal received from the connection detecting unit 52 when the logic operation unit 51 receives the alarm signal having the logic value corresponding to the detection of the alarm condition from the alarm control unit 10. Thus, the sound signal output unit 30 is converted to be capable of outputting the alarm sound through the speaker 60 when the alarm condition is detected.

For example, the logic operation unit 51 may have an OR gate. The speaker amp 32 may be disabled when the logic value outputted from the logic operation unit 51 is ‘0’. At this time, the alarm control unit 10 may output the alarm signal having the logic value ‘1’ when the alarm condition is detected. Also, the connection detecting unit 52 may output the detection signal having the logic value ‘0’ when the external speaker 70 is connected. Accordingly, the speaker amp 32 became disabled when the alarm condition is not detected and also the external speaker 70 is connected with the connection detecting unit 52.

Besides, the logic operation unit 51 may have any other circuit capable of enabling the speaker amp 32 to output the speaker sound signal regardless of whether or not the external speaker 70 is Connected with the external connection terminal 34 when the alarm condition is detected.

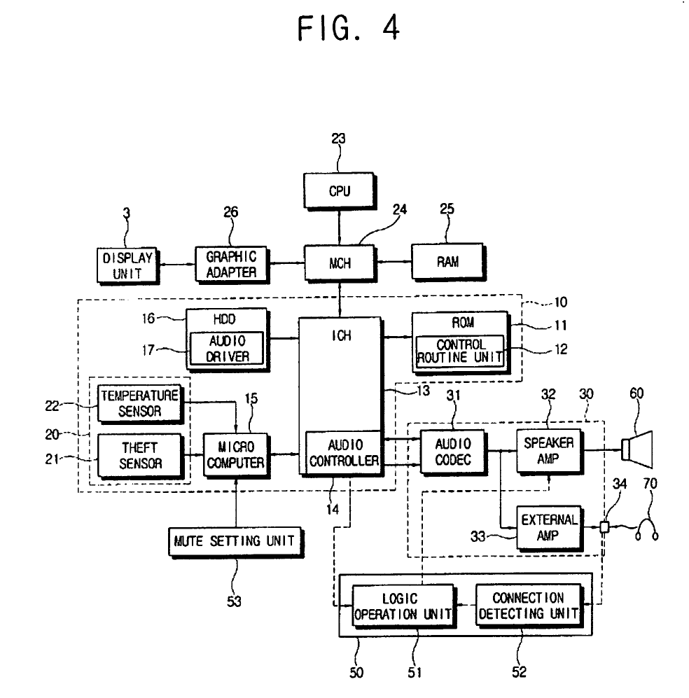

The computer 100 according to an embodiment of the present invention will be described below in more detail by referring to FIG. 4.

As shown in FIG. 4, the computer 100 may comprise a central processing unit (CPU) 23, a graphic adapter 26 outputting a video signal to the display unit 3, a memory control hub (MCH) 24, and an input/output control hub (ICH) 13.

The memory control hub 24 is a chip set controlling both a random access memory (RAM) 25 as a main memory and data transferred from/to CPU 23, the RAM 25, and the graphic adapter 26. Here, the graphic adapter 26 may combined with the memory control hub 24 to form one chip set, for example, a graphic memory control hub (GMCH).

The input/output control hub 13 is the chip set controlling the data transferred from/to hardware except the hardware connected with the memory control hub 24. For example, as shown in FIG. 4, the input/output control hub 13 may be the chip set controlling the data transferred from/to a read only memory (ROM) 11, a hard disk drive (HDD) 16, the sound signal output unit 30, and a microcomputer 15.

The sound signal output unit 30 may comprise the audio codec 31, the speaker amp 32, the external output amp 33 and the external connection terminal 34.

Here, the audio codec 31 converts the sound data inputted from an audio controller 14 into the analog sound signal, and then outputs the analog sound signal. In FIG. 4, the audio controller 14 is a part of the input/output control hub 13, but may be a separate chip set.

The audio controller 14 outputs the sound data to the audio codec 31 or performs other functions according to a control of an audio driver 17 installed and then stored beforehand in the hard disk drive 16.

As shown in FIG. 4, the alarm control unit 10 of the computer 100 may comprise: an alarm detecting unit 20 detecting the alarm condition; and an alarm generating unit responding to the alarm condition when the alarm detecting unit 20 detects the alarm condition and controlling the speaker output control unit 50 and/or the sound signal output unit 30.

The alarm generating unit controls the speaker output control unit 50 so that the sound signal output unit 30 is activated to output the speaker sound signal when the alarm detecting unit 20 detects the alarm condition. Also, the alarm generating unit controls the sound signal output unit 30 so that the speaker 60 generates the alarm sound to correspond to the alarm condition.

Here, the alarm generating unit, as shown in FIG. 4, comprises the microcomputer 15, the audio controller 14, and a control routine unit 12.

The microcomputer 15 determines whether a current condition of the computer 100 belongs to the alarm condition based on a signal inputted from the alarm detecting unit 20. Further, when the microcomputer 15 determines that the current condition of the computer 100 belongs to the alarm condition, the microcomputer 15 outputs an interrupt signal.

The interrupt signal outputted from the microcomputer 15 is supplied to the control routine unit 12 stored in the ROM 11 via the CPU 23. At this moment, the control routine unit 12 controls the audio controller 14 according to the interrupt signal so that the sound signal output unit 30 outputs the alarm sound through the speaker 60. The control routine unit 12 may be a part of a BIOS (Basic Input/Output System). Also, the control routine unit 12 may be a part of any hardware of the computer 100 capable of controlling the audio controller 14 to respond to the interrupt signal outputted from the microcomputer 15.

The audio controller 14 controls the audio codec 31 to output the alarm sound according to a control of the control routine unit 12. Then, the audio controller 14 controls the audio codec 31 to output the PC beep signal provided in the audio codec 31.

When the microcomputer 15 determines the current condition of the computer 100 belongs to the alarm condition, the alarm generating unit outputs the alarm signal having the logic value corresponding to the alarm condition to the logic operation unit 51. Here, the alarm signal outputted to the logic operation unit 51 may be outputted from either the microcomputer 15 of the alarm generating unit or the audio controller 14.

The alarm signal outputted from the alarm generating unit is inputted to the logic operation unit 51, and the logic operation unit 51 enables the speaker amp 32 of the sound signal output unit 30 to be activated according to the inputted alarm signal.

The alarm detecting unit 20 detects the alarm condition of the computer 100. As shown in FIG. 4, the alarm detecting unit 20 may comprise a temperature sensor 22 and/or a theft sensor 21.

The temperature sensor 22 senses the temperature of a certain element of the computer 100, that is, the temperature of the CPU 23, for example. Here, information about the temperature of the CPU 23 sensed by the temperature sensor 22 is supplied to the microcomputer 15, and the microcomputer 15 generates the interrupt signal based on the information about the temperature of the CPU 23 supplied from the temperature sensor 22 if the temperature of the CPU 23 rises up to a preset degree or more.

The theft sensor 21 detects whether the computer 100 is in a theft condition. For example, the theft sensor 21 may be disposed at a lower surface of the main body 1 of the computer 100, and supplies a corresponding signal to the microcomputer 15 if the theft sensor 21 detects the computer 100 is lifted up from the installation surface. Also, when the computer 100 is combined with a docking station, the theft sensor 21 detects whether the computer 100 is separated from the docking station, thereby detecting whether the computer 100 is the theft condition. Besides, any theft senor 21 capable of detecting whether the computer 100 is in the theft condition can be employed in the present invention.

As shown in FIG. 4, the computer 100 may further comprise a mute setting unit 53. When a user sets a mute function in the computer 100 by the mute setting unit 53, the audio driver 17 controls the audio controller 14 not to output the sound data to the audio codec 31.

When the microcomputer 15 generates the interrupt signal, the control routine unit 12 informs the audio driver 17 that the alarm condition is detected. Then, if the mute function is set in the mute setting unit 53, the audio driver 17 controls the audio controller 14 to cancel the mute function. Accordingly, even when the sound data corresponding to the alarm sound is inputted to the audio codec 31 by the audio controller 14, the audio controller 14 cancels the mute function if the alarm condition is detected, whereby the alarm sound is outputted through the speaker 60.

Here, the mute setting unit 53 may be a so-called “hot-key” provided at a portion of the main body 1. Also, the mute function of the computer 100 may be set through a graphic use interface (not shown) provided by the audio driver 17.

Although, in the above description, the alarm condition is detected by a sensor such as the temperature sensor 22, the theft sensor 21, and the like, the alarm condition may be detected by any other way capable of detecting whether the computer 100 is in the alarm condition. For example, when the computer 100 is turned on, a preset password may be required to initialize the computer 100. If a password inputted in the computer 100 is inconsistent with the preset password at least a predetermined number of times, the control routine unit 12 of the alarm control unit 10 may control the audio controller 14 so that the sound signal output unit 30 outputs the alarm sound through the speaker 60. In this case, it is preferable that the control routine unit 12 be a part of the BIOS performing an system initialization, and the BIOS may control the sound signal output unit 30 and/or the speaker output control unit 50 by the audio controller 14.

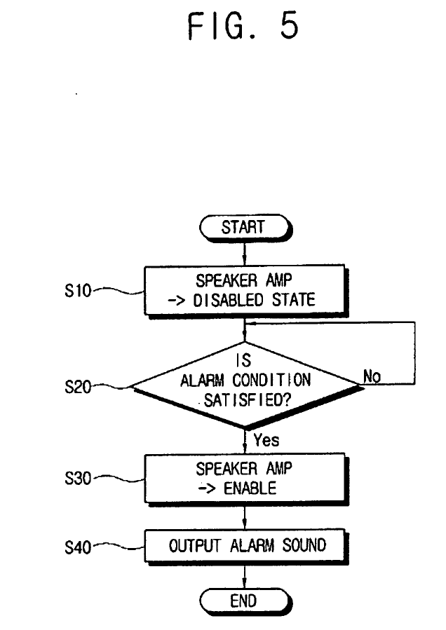

A control process of the computer 100 according to an embodiment of the present invention is shown in FIG. 5 and will be described below by referring to FIGS. 1-5.

First, when the computer 100 cannot output the sound through the speaker 60, for example, when the external speaker 70 is connected with the external connection terminal 34 and the speaker amp 32 is disabled from being activated at operation 10, the alarm control unit 10 detects whether the alarm condition is satisfied by the alarm detecting unit 20 at operation 20.

Then, if the alarm condition is detected, the alarm control unit 10 controls the speaker output control unit 51 so that the speaker amp 32 is enabled at operation 30, and also controls the sound signal output unit 30 so that the alarm sound is outputted through the speaker 60 at operation 40.

As described above are provided the sound signal output unit 30 outputting the speaker sound signal to the speaker, the speaker output control unit 50 controlling whether the sound signal output unit 30 outputs the speaker sound signal, and the alarm control unit 10 controlling the speaker output control unit 50 if the predetermined alarm condition is detected so that the sound signal output unit 30 outputs the speaker sound signal and also controlling the sound signal output unit 30 so that the alarm sound is outputted through the speaker 60 to correspond to the alarm condition. With this configuration, a condition of the speaker 60 being disabled is cancelled when the alarm condition is detected, and the alarm sound is outputted through the speaker 60.

Although a few embodiments of the present invention have been shown and described, the present invention is not limited to the described embodiments. Instead, it would be appreciated by those skilled in the art that changes may be made to these embodiments without departing from the principles and spirit of the invention, the scope of which is defined by the claims and their equivalents.

What is claimed is:

1. A computer having a speaker outputting a sound, the computer comprising:
a sound signal output unit outputting a speaker sound signal to the speaker;
a speaker output control unit controlling whether the sound signal output unit outputs the speaker sound signal; and
an alarm control unit controlling the speaker output control unit so that the sound signal output unit outputs the speaker sound signal when a predetermined alarm condition is detected, and controlling the sound signal output unit so that the speaker generates a preset alarm sound corresponding to the alarm condition.

2. The computer of claim 1, wherein the sound signal output unit comprises an audio codec converting an input signal into an analog sound signal and a speaker amplifier outputting the speaker sound signal by amplifying the analog sound signal output from the audio codec, and
wherein the speaker output control unit controls activation of the speaker amplifier, and whether the speaker sound signal is output.

3. The computer of claim 2, wherein the sound signal output unit further comprises an external output amplifier outputting an external output sound signal by amplifying the analog sound signal output from the audio codec, and an external connection terminal with which an external speaker is connected in order to output the external output sound signal to the external speaker, and
wherein the speaker output control unit comprises a connection detecting unit detecting whether the external speaker is connected with the external connection terminal, and a logic operation unit controlling the speaker amplifier to output the speaker sound signal regardless of whether the external speaker is connected with the external connection terminal when the alarm condition is detected.

4. The computer of claim 3, wherein the logic operation unit controls the speaker amplifier to not output the speaker sound signal when the connection detecting unit detects the external speaker is connected when the alarm condition is not detected.

5. The computer of claim 3, wherein the alarm control unit comprises:
an alarm detecting unit detecting the alarm condition; and
an alarm generating unit controlling the speaker output control unit and/or the sound signal output unit to respond to the alarm condition when the alarm detecting unit detects the alarm condition.

6. The computer of claim 5, wherein the alarm generating unit comprises:
an audio controller supplying sound data to the audio codec;
a microcomputer generating a predetermined interrupt signal when the alarm detecting unit detects the alarm condition; and
a control routine unit controlling the audio controller so that the sound signal output unit outputs the alarm sound through the speaker according to the interrupt signal generated from the microcomputer.

7. The computer of claim 6, wherein either the microcomputer or the audio controller outputs a signal corresponding to a detecting result of the alarm detecting unit to the logic operation unit.

8. The computer of claim 6, wherein the control routine unit performs a system initializing process when the computer is turned on, requests input of a preset password while performing the system initializing process, and controls the audio controller so that the sound signal output unit outputs the alarm sound through the speaker when a password input in response to a request to input a preset password is inconsistent with the preset password at least equal to a predetermined number of times.

9. The computer of claim 1, further comprising a mute setting unit which, prevents the generation of the present alarm sound when the alarm condition is detected.

10. A control method of a computer having a speaker outputting a sound and a sound signal output unit outputting a speaker sound signal through the speaker, the control method comprising:
disabling the sound signal output unit from being activated;
detecting whether a predetermined alarm condition exists; and
enabling the sound signal output unit so that a preset alarm sound corresponding to the alarm condition is output through the speaker when the alarm condition is detected.

11. The control method of the computer as claimed in claim 10, wherein the sound signal output unit comprises a speaker amplifier amplifying an analog sound signal into a speaker sound signal and outputting the speaker sound signal, an external output amplifier amplifying the analog sound signal into an external output sound signal and outputting the external output sound signal, and an external connection terminal with which an external speaker is connected so that the external output sound signal is outputted to the external speaker, and
wherein the disabling the sound signal output unit comprises disabling the speaker amplifier from being activated when the external connection terminal is connected with the external speaker.

12. The control method of the computer as claimed in claim 11, wherein the enabling the sound signal output unit comprises enabling the speaker amplifier to be activated regardless of whether the external speaker is connected with the external connection terminal when the alarm condition is detected.
